(19) United States
(12) Patent Application Publication
(10) Pub. No.: US 2006/0023264 A1
(43) Pub. Date: Feb. 2, 2006

(54) High-speed image scanning system and the method thereof

(75) Inventor: Ho-Min Chung, Taipei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Lite-On Technology Corporation

(21) Appl. No.: 11/067,766

(22) Filed: Feb. 28, 2005

(30) Foreign Application Priority Data
Jul. 28, 2004 (TW) 93122532

(51) Int. Cl. G03F 3/08

(52) U.S. Cl. 358/448; 358/518

(57) ABSTRACT

A high-speed image scanning system and the corresponding method are disclosed. A high-speed photo sesnor, which can simultaneously output several sets of RGB color signals cooperates with the converter controlling unit and memory controlling unit of an ASIC so that several sets of analog/digital (A/D) converters and memories can be operated in parallel. Accordingly, an external analog image can be outputted to a processing terminal at a high speed.

### BACKGROUND OF THE INVENTION

1. Field of Invention

The invention relates to an image scanning system and the method thereof. In particular, the invention relates to a system and a method, which can process high-speed image scanning in an image scanning device.

2. Related Art

With continuous improvement in the hardware and software of image scanning devices, almost all of them can achieve certain scanning qualities (i.e. sufficiently good resolutions). They can satisfy the image scanning quality required by oridinary or even professional users.

The conventional image scanning system, as shown in FIG. 1, contains a photo sensor 100, an analog/digital (A/D) converter 110, an application specific processing unit (usually an ASIC, application specific integrated circuit) 120, and a memory 130. To scan an image, the photo sensor 100 first extracts the analog image of an external object, and outputs its analog signals in RGB colors. The A/D converter converts the received analog signals into digital signals, which are then outputted to the application specific processing unit 120. The digital signals processed by the application specific processing unit 120 is stored in the memory 130, and at an appropriate moment, the final image signals is outputted to a processing terminal 140 via an interface converter 140, which is connected to the processing terminal 140 for further processing.

The application specific processing unit 120 performs basic digital signals processing. It mainly consists of the following components: (1) a data gate 121 and an image processing unit 122 for image processing; (2) a buffer unit 123 for temporarily holding data during image processing; (3) an ouptut recombination unit 124 for sorting the image signals; and (4) a transmission interface 125 for outputting the image signals. The detailed operations among different components of the application specific processing unit 120 are well-known and therefore, are not to be further described herein.

From the above description, it can be seen that the operation of the conventional image scanning system is step-by-step. That is, the photo sensor 100, the A/D converter 110, and the memory 130 have a one-to-one relation. One analog signals outputted by the photo sensor 100 is sent to one A/D converter for signals conversion. The digital signals processed by the application specific processing unit 120 is stored by one memory 130, too.

However, this type of processing mode has become the bottleneck of the scanning speed in all image scanning devices. Thus, how to further improve the image scanning speed while the scanning quality of most image scanning devices can still satisfy users' needs is the focus of future research in image scanning devices.

### SUMMARY OF THE INVENTION

In view of the foregoing, the invention provides a high-speed scanning system and the method thereof. The invention improves the main factors which will slow down the scanning speed of conventional image scanning systems to greatly increase the image scanning speed.

The main technicality of the invention is to use a high-speed photo sensor which can simultaneously output several sets of RGB color signals, and the converter controlling unit and memory controlling unit in the application specific processing unit, and thus the A/D converters and memories can be operated in parallel, and an external analog image can be outputted to a processing terminal at a high speed.

To achieve the above objective, the disclosed system contains: (1) a high-speed photo sensor with a plurlaity of photo sensing units; (2) an A/D converter module with a plurality of A/D converters; (3) a memory module with a plurality of memories; and (4) an application specific processing unit with a converter controlling unit and a memory controlling unit.

The disclosed method includes the steps of: outputting a plurality of analog signals converted from an image captured by the photo sensing units in a high-speed photo sensor; performing signals conversion for the analog signals received by the A/D converters using the converter controlling unit; the converters' outputting the converted digital signals to a data gate and an image processing unit for image processing; the memory controlling unit's actively distributing the processing digital signals to the memories; the memory controlling unit's extracting the digital signals from the memories and using an output recombination unit to sort the image; and outputting the sorted image signals to the processing terminal via a transmission interface.

### BRIEF DESCRIPTION OF THE DRAWINGS

The invention will become more fully understood from the detailed description given hereinbelow illustration only, and thus are not limitative of the present invention, in which

FIG. 1 is a schematic view of a conventional image scanning system;

FIG. 2 is a schematic view of the disclosed high-speed image scanning system;

FIG. 3 is a flowchart of the disclosed high-speed image scanning method; and

FIG. 4 is a schematic view of an embodiment of the disclosed invention.

### DETAILED DESCRIPTION OF THE INVENTION

The disclosed system and method are mainly used in image scanning devices, such as scanners, MFP(multi-function peripheral), etc. The invention enables the image scanning device to complete image scanning at a higher speed for other processing terminal 150 (such as PC) to use.

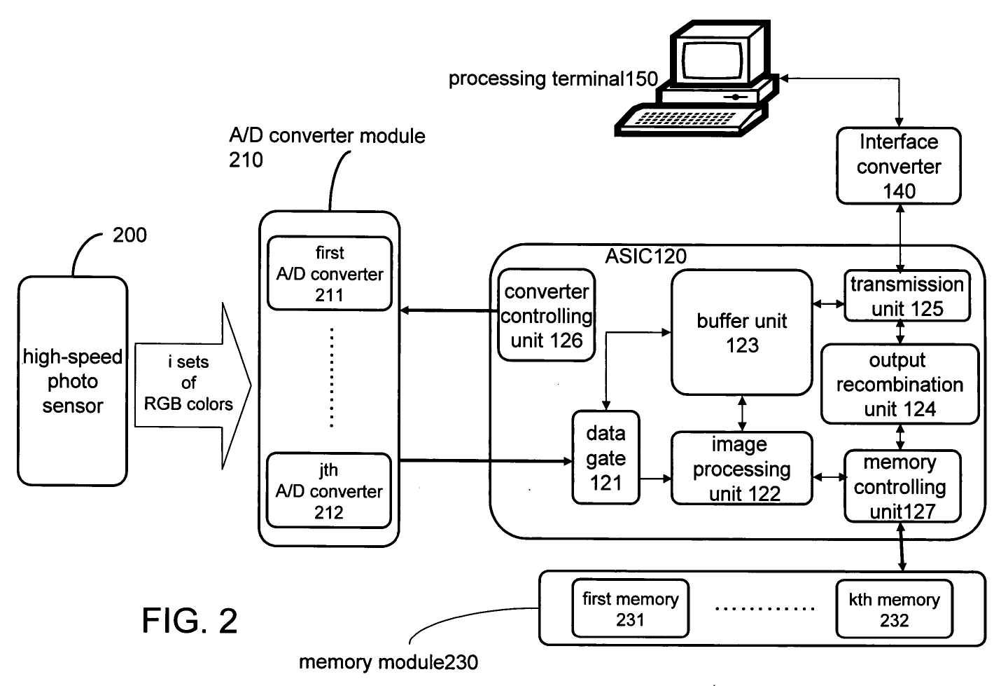

The disclosed system, as shown in FIG. 2, contains the following components: (1) The high-speed photo sensor 200 has several sets of static arrayed photo sensing units to simultaneously process an image extracted from the exterior and to output several sets of analog signals. The preferred embodiment includes the charge coupled device (CCD) or the contact image sensor (CIS).

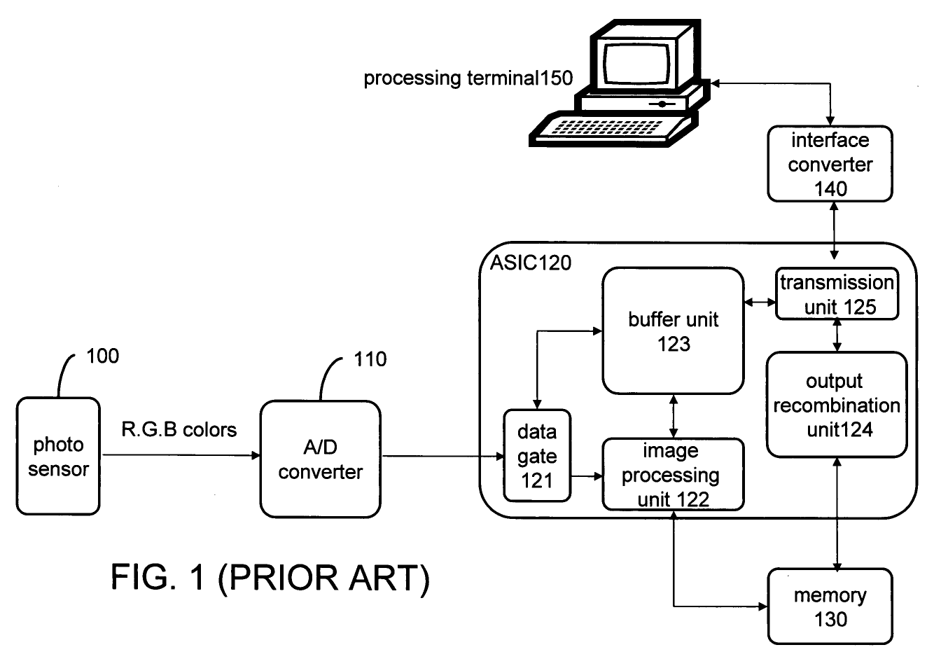

The high-speed photo sensor 200 is the primary feature of the invention. In comparison with the conventional photo sensor 100 (see FIG. 1), the disclosed high-speed photo sensor 200 can complete the analog signals x several times faster for the same image. (The actual times depend on how many sets of analog signals outputs the high-speed photo sensor 200 has. As shown in FIG. 2, there are i sets of analog signals outputs.)

The analog signals herein refer to the RGB color signals. Usually, the RGB color signals can be contained in one set of analog signals. Sometimes, the RGB color signals can be separated in different sets of analog signals.

(2) The A/D converter module 210 has several sets of A/D converters. They can simultaneously accept the analog signals sent from the high-speed photo sensor 200 and convert them into digital signals.

The A/D converter module 210 is another feature of the invention. In comparison with the single A/D converter 110 (As shown in FIG. 1) in the conventional scanning system, the invention can greatly increase the signals conversion speed. (Actually, the acutal conversion speed is determined by the number of A/D converters in the module 210. For example, FIG. 2 has the first to the jth A/D converters 211, 212.)

It should be emphasized that in the disclosed system, the analog signals outputted by the high-speed photo sensor 200 and the A/D converters in the A/D converter module 210 have a many-to-many (or non-one-to-one) corresponding relation. The number of analog signals and the A/D converters do not need to be the same. They can be determined by the actual design.

(3) The application specific processing unit 120 is the part that receives the digital signals and processes the image. The processed image signals is provided to the processing terminal 150.

In the invention, the application specific processing unit 120 has two parts. The first part is the same as the conventional application specific processing unit, containing a data gate 121, an image processing unit 122, a buffer unit 123, an output recombinaiton unit 124, and a transmission interface 125. The second part is a feature of the invention, containing a converter controlling unit 126 and a memory controlling unit 127.

Since the techniques in the first part belongs to the prior art, we only make a brief description here. (a) The data gate 121 connects to the A/D converter module 210 to receive the digital signals transmitted from the A/D converters 211, 212 for image processing. The processed digital signals are sent to the image processing unit 122. (b) The image processing unit 122 connects to the data gate 121. It receives the processed digital signals, performs subsequent image processing, and stores the digital signals in the memory module 230 via the memory controlling unit 127. (c) The buffer unit 123 temporarily holds the digital signals during the image processing of the data gate 121 and the image processinng unit 122. (d) The output recombination unit 124 connects to the memory controlling unit 127 to extract the digital signals stored in the memories 231, 232 and to re-order them. The final image signals thus obtained are sent to the processing terminal 150. (e) The transmission interface 125 connects to the output recombination unit 124. It transmits the final image signals to the processing terminal 150 via the interface converter 140.

The converter controlling unit 126 and the memory controlling unit 127 in the second part are features of the invention. The converter controlling unit 126 connects to the A/D converter module 210 to control how the A/D converters 211, 212 operate in parallel according to the requirements of image processing. For example, the way to receive the analog signals and the number of operating A/D converters which are usually determined by how the high-speed photo sensor 200 operates. The memory controlling unit 127 connects to the memory module 230 to control the access to all the memories 231 232. For example, the number of working memories and how the memories are allocated which are usually determined by the conditions of image scanning. After the image processing unit 122 finishes processing the digital signals, the memory controlling unit 127 actively distributes all the digital signals in parallel to the memories.

(4) The memory module 230 contains several memories (e.g. the first memory 231 to the kth memory 232). According to the commands from the memory controlling unit 127, the memory module 230 executes parallel digital signals reception, storage, and output.

The memory module 230 is also a feature of the invention. Note that the number of analog signals outputted by the high-speed photo sensor 200, the number of the A/D converters for receiving the analog signals, and the number of memories in the memory module 230 have a many-to-many (or non-one-to-one) corresponding relation. Their numbers do not need to be the same and can be determined by the actual design.

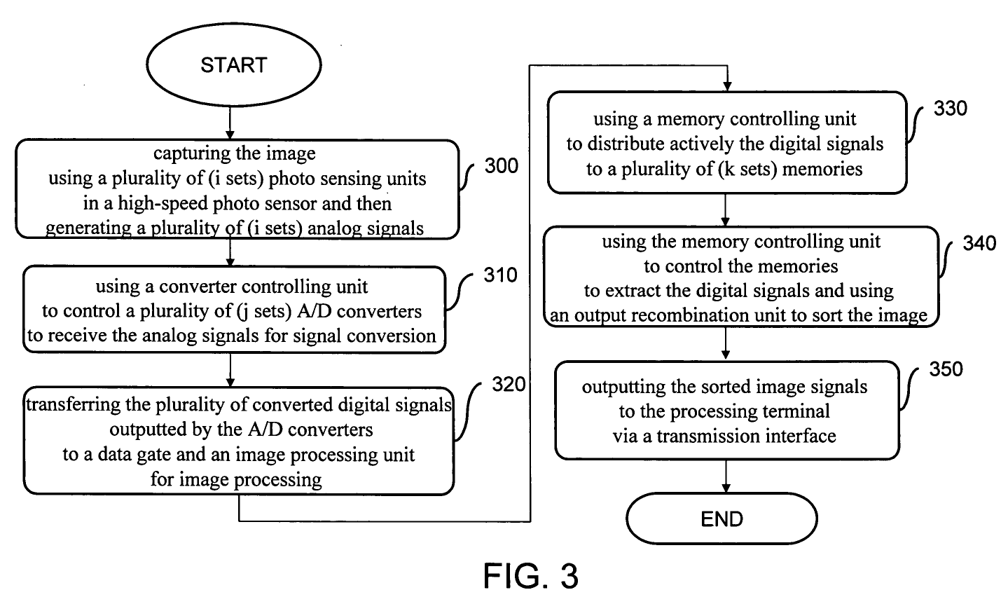

The disclosed method of the invention is described with reference to FIG. 3 as follows. First, the photo sensing units in the high-speed photo sensor 200 captures an image and converts it into several analog signals (step 300). The converter controlling unit 126 controls the A/D converters 211, 212 to receive the analog signals for signals conversion (step 310), converting the analog signals into digital signals that can be processed by the application specific processing unit 120. The data gate 121 and the image processing unit 122 in the application specific processing unit 120 processes the converted digital signals (step 320). During the process, the buffer unit 123 is used to temporarily store data to increase the processing speed. After processing the digital signals, the digital signals are actively distributed by the memory controlling unit 127 to the meories 231, 232 in the memory module 230 (step 330). The memory controlling unit 127 extracts the digital signals in the memories and sends them to the output recombination unit 124 to sort the image (step 340). Finally, the output recombination unit 124 sends the sorted image signals to the processing terminal 150 via the transmission interface 125 (step 350). The transmission interface 125 uses the interface converter 140 between it and the processing terminal 150 to complete the image signals transmissions.

The disclosed method is featured in that it has several sets of analog signals outputted in parallel. Using a controller to control the A/D converters perform signals conversion at the same time. During the image processing, several memories are controlled by the controller to receive, store and output signals. Thus, the overall speed can be greatly increased. To illustrate the feasibility of the disclosed system and method, we further use the following embodiment to explain the invention.

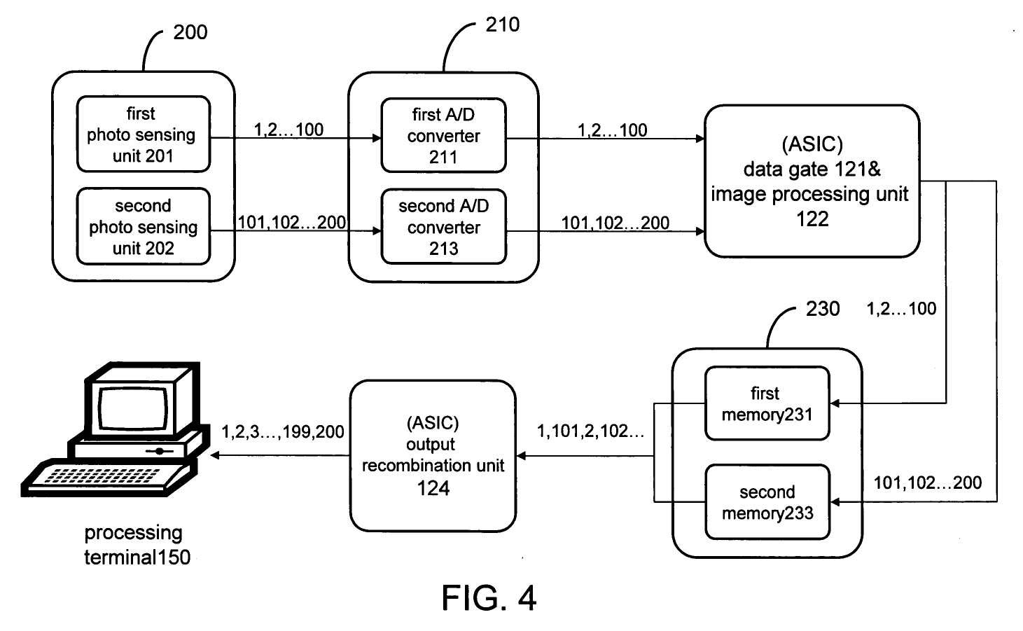

With reference to FIG. 4, this embodiment has the following premises. The image extracted from the exterior has 200 pixels. The high-speed photo sensor 200 has two sets of photo sensing units (i.e. the first photo sensing unit 201 and the second photo sensing unit 202). The A/D converter module 210 has two A/D converters (i.e. the first A/D converter 211 and the second A/D converter 213), both controlled by the converter controlling unit 126. The memory module 230 has two memories (i.e the first memory 231 and the second memory 233), both controlled by the memory controlling unit 127.

First, the first photo sensing unit 201 and the second photo sensing unit 202 in the high-speed photo sensor 200 simultaneously and homogeneously extract the 200 image pixels. The analog signals of the first to the 100^{th} pixels are processed by the first photo sensing unit 201. The 101th to the 200^{th} pixels are processed by the second photo sensing unit 202. In this embodiment, each analog signals contains RGB color signals. However, different high-speed photo sensor designs may have individual color signals in each analog signals.

Under the control of the converter controlling unit 126, the analog signals outputted by the first photo sensing unit 201 is received by the first A/D converter 211. The analog signals outputted by the second photo sensing unit 202 is received by the second A/D converter 213. All the analog signals are converted into digital signals by parallel processing and outputted to the application specific processing unit 120. The first A/D converter outputs the digital signals of the first to the 100^{th} pixels. The second A/D converter outputs the digital signals of the 101th to the 200^{th} pixels. According to the settings of the converter controlling unit 126, one may adopt the non-one-to-one method.

After the digital signals enter the application specific processing unit 120, the data gate 121 and the image processing unit 122 perform image processing. Afterwards, the memory controlling unit 127 distributes all the digital signals to the first memory 231 and the second memory 233. In this embodiment, the signals are evenly distributed. Thus, the digital signals of the first to the 100^{th} pixels are stored in the first memory 231. Those of the 101th to the 200^{th} pixels are stored in the second memory 233. However, one may also adopt an uneven distribution scheme according to the settings of the memory controlling unit 127.

Finally, the memory controlling unit 127 extracts the digital signals stored in the memories (in the order of the first, the 101th, the second, the 102th, etc) and provides them to the output recombination unit 124 of the application specific processing unit 120 for re-ordering the image signals. Finally, the image signals are in the correct order (i.e. the first, the second, the third, . . . , the 199^{th}, the 200^{th}). Through the connection of the transmission interface 125 and the interface converter 140, the image signals are outputted to the processing terminal 150. This completes the high-speed image scanning process.

Certain variations would be apparent to those skilled in the art, which variations are considered within the spirit and scope of the claimed invention.

What is claimed is:

1. A high-speed image scanning system for processing an analog image captured from the exterior at a high speed and outputting the processed digital image signals to a processing terminal, the high-speed image scanning system comprising:
a high-speed photo sensor, which has a plurality of (i sets) photo sensing units to simultaneously process the captured image in parallel and output correspondingly a plurality of analog signals (i sets);
an A/D converter module, which has a plurality of (j sets) A/D converters to receive and process in parallel the analog signals and to convert the analog signals into a plurality of digital signals;
a memory module, which has a plurality of (k sets) memories to receive, store, and output in parallel the digital signals; and
an application specific processing unit, which receives the digital signals for image processing and outputs a plurality of recombined image signals for the processing terminal to use, the application specific processing unit comprising:
a converter controlling unit, which connects to the A/D converter module to control how the A/D converters operate in parallel; and
a memory controlling unit, which connects to the memory module to control how the memories operate in parallel.

2. The high-speed image scanning system of claim 1, wherein the high-speed photo sensor is a contact image sensor (CIS).

3. The high-speed image scanning system of claim 1, wherein the high-speed photo sensor is a charge coupled device (CCD).

4. The high-speed image scanning system of claim 1, wherein the photo sensing units are disposed in a static array.

5. The high-speed image scanning system of claim 1, wherein the analog signal includes the RGB color signals.

6. The high-speed image scanning system of claim 1, wherein the analog signal contains one of the RGB color signals.

7. The high-speed image scanning system of claim 1, wherein the application specific processing unit contains:
a data gate, which connects to the A/D converter module to receive the digital signals from the A/D converters for image processing;
an image processing unit, which connects to the data gate to receive the digital signals for image processing;
a buffer unit, which temporarily holds data when the data gate and the image processing unit are processing the image; and
an output recombination unit, which connects to the memory controlling unit to recombine the digital signals extracted from the memories.

8. The high-speed image scanning system of claim 1, wherein the application specific processing unit contains a transmission interface in connection with an interface converter of the processing terminal for transmitting the image signal.

9. The high-speed image scanning system of claim 1, wherein the application specific processing unit is an ASIC.

10. The high-speed image scanning system of claim 1, wherein i, j, and k are equal natural numbers greater than 1.

11. The high-speed image scanning system of claim 1, wherein i, j, and k are unequal natural numbers greater than 1.

12. A high-speed image scanning method for processing an analog image captured from the exterior at a high speed and outputting the processed digital image signals to a processing terminal, the method comprising the steps of:
capturing the image using a plurality of (i sets) photo sensing units in a high-speed photo sensor and then generating a plurality of (i sets) analog signals;
using a converter controlling unit to control a plurality of (j sets) A/D converters to receive the analog signals for signal conversion;
transferring the plurality of converted digital signals outputted by the A/D converters to a data gate and an image processing unit for image processing;
using a memory controlling unit to distribute actively the digital signals to a plurality of (k sets) memories;
using the memory controlling unit to control the memories to extract the digital signals and using an output recombination unit to sort the image; and
outputting the sorted image signals to the processing terminal via a transmission interface.

13. The method of claim 12, wherein the high-speed photo sensor is a CIS.

14. The method of claim 12, wherein the high-speed photo sensor is a CCD.

15. The method of claim 12, wherein the photo sensing units are disposed in a static array.

16. The method of claim 12, wherein the analog signal includes the RGB color signals.

17. The method of claim 12, wherein the analog signal contains one of the RGB color signals.

18. The method of claim 12, wherein the processing terminal connects to the transmission interface via an interface converter to transmit the image signals.

19. The method of claim 12, wherein i, j, and k are equal natural numbers greater than 1.

20. The method of claim 12, wherein i, j, and k are unequal natural numbers greater than 1.
